(19) United States
(12) Patent Application Publication
(10) Pub. No.: US 2015/0191821 A1
(43) Pub. Date: Jul. 9, 2015

(54) SUBSTRATE PROCESSING DEVICE

(71) Applicant: EUGENE TECHNOLOGY CO., LTD., Gyeonggi-do (KR)

(72) Inventors: Il-Kwang Yang, Gyeonggi-do (KR); Byoung-Gyu Song, Gyeonggi-do (KR); Kyong-Hun Kim, Gyeonggi-do (KR); Yong-Ki Kim, Chungcheongnam-do (KR); Yang-Sik Shin, Gyeonggi-do (KR)

(73) Assignee: EUGENE TECHNOLOGY CO., LTD., Gyeonggi-do (KR)

(21) Appl. No.: 14/419,775

(22) PCT Filed: Aug. 23, 2013
(86) PCT No.: PCT/KR2013/007567

§ 371 Date: Feb. 5, 2015

(30) Foreign Application Priority Data
Aug. 28, 2012 (KR) 10-2012-0094385

(51) Int. Cl. C23C 16/46; C23C 16/44; C23C 16/458

(52) U.S. Cl. CPC C23C 16/46; C23C 16/458; C23C 16/4412

(57) ABSTRACT

Provided is a substrate processing apparatus. The substrate processing apparatus in which a process with respect to a substrate is performed includes a chamber body having an opened upper side, the chamber body including a passage defined in a side thereof so that the substrate is loaded or unloaded through the passage, a chamber cover disposed on the chamber body to cover the opened upper side of the chamber body, the chamber cover providing a process space in which the process with respect to the substrate is performed, a susceptor disposed within the process space to heat the substrate, and a heating block disposed on an upper or lower portion of the passage to preliminarily heat the substrate loaded through the passage.

### TECHNICAL FIELD

The present invention disclosed herein relates to an apparatus for processing a substrate, and more particularly, to a substrate processing apparatus in which upper and lower heating blocks are installed on a passage to perform preliminary heating on a substrate.

### BACKGROUND ART

A semiconductor device includes a plurality of layers on a silicon substrate. The layers are deposited on the substrate through a deposition process.

The deposition process has several important issues that are important to evaluate the deposited layers and select a deposition method.

First, one example of the important issues is ‘quality’ of each of the deposited layers. The ‘quality’ represents composition, contamination levels, defect density, and mechanical and electrical properties. The composition of the deposited layer may be changed according to deposition conditions. This is very important to obtain a specific composition.

Second, another example of the issues is a uniform thickness over the wafer. Specifically, a thickness of a layer deposited on a pattern having a nonplanar shape with a stepped portion is very important. Here, whether the thickness of the deposited film is uniform may be determined through a step coverage which is defined as a ratio of a minimum thickness of the film deposited on the stepped portion divided by a thickness of the film deposited on the pattern.

The other issue with respect to the deposition may be a filling space. This represents a gap filling in which an insulating layer including an oxide layer is filled between metal lines. A gap is provided to physically and electrically isolate the metal lines from each other.

Among the issues, uniformity is one of very important issues with respect to the deposition process. A non-uniform layer may cause high electrical resistance on the metal lines to increase possibility of mechanical damage.

### DISCLOSURE

### Technical Problem

The present invention provides a substrate processing apparatus in which upper and lower heating blocks are installed on a passage to perform preliminary heating on a substrate before the substrate is loaded on a susceptor.

Further another object of the present invention will become evident with reference to following detailed descriptions and accompanying drawings.

### Technical Solution

Embodiments of the present invention provide substrate processing apparatuses, the substrate processing apparatus including: a chamber body having an opened upper side, the chamber body including a passage defined in a side thereof so that a substrate is loaded or unloaded through the passage; a chamber cover disposed on the opened upper side of the chamber body to cover the opened upper side of the chamber body, the chamber cover providing a process space in which the process with respect to the substrate is performed; a susceptor disposed within the process space to heat the substrate disposed on a upper surface of the susceptor; a heating block disposed on an upper or lower portion of the passage to preliminarily heat the substrate loaded through the passage; and an end effector moving with the substrate through the passage and loading the substrate on the upper surface of the susceptor.

In some embodiments, the chamber body may have upper and lower openings that are respectively defined in the upper and lower portions of the passage, and the substrate processing apparatuses may include: an upper heating block fixed to the upper opening, the upper heating block having an upper installation space separated from the process space; and a lower heating block fixed to the lower opening, the lower heating block having a lower installation space separated from the process space.

In other embodiments, an upper side of the upper heating block and a lower side of the lower heating block may be opened, and the substrate process apparatuses may include: an upper cover covering the opened upper side of the upper heating block to isolate the upper installation space from the outside; and a lower cover covering the opened lower side of the lower heating block to isolate the lower installation space from the outside.

In still other embodiments, the substrate processing apparatuses may further include a nozzle ring disposed outside the susceptor to surround the susceptor, the nozzle ring spraying an inert gas upward.

In even other embodiments, the chamber body may have an exhaust passage defined in a side opposite to the passage, and the substrate process apparatuses may further include a flow guide disposed outside the susceptor to guide the process gas toward the exhaust passage, wherein the flow guide may include: a circular guide part having an arc shape that is concentric with the susceptor, the circular guide having a plurality of guide holes; and linear guide parts connected to both sides of the circular guide part and disposed on both sides of the susceptor, respectively, each of the linear guide parts having a guide surface that is substantially parallel to a loading direction of the substrate.

### ADVANTAGEOUS EFFECTS

According to the embodiment of the present invention, since the upper and lower heating blocks are installed on the passage to preliminarily heat the substrate before the substrate is loaded on the lift pin, a time required for heating the substrate by using the susceptor during the deposition process may be reduced to improve productivity.

### DESCRIPTION OF DRAWINGS

FIG. 1 is a schematic view of a substrate processing apparatus according to an embodiment of the present invention;

FIG. 2 is a schematic view illustrating a process progression state of the substrate processing apparatus of FIG. 1; and

FIG. 3 is a cross-sectional view illustrating a process space of the substrate processing apparatus of FIG. 1.

### BEST MODE

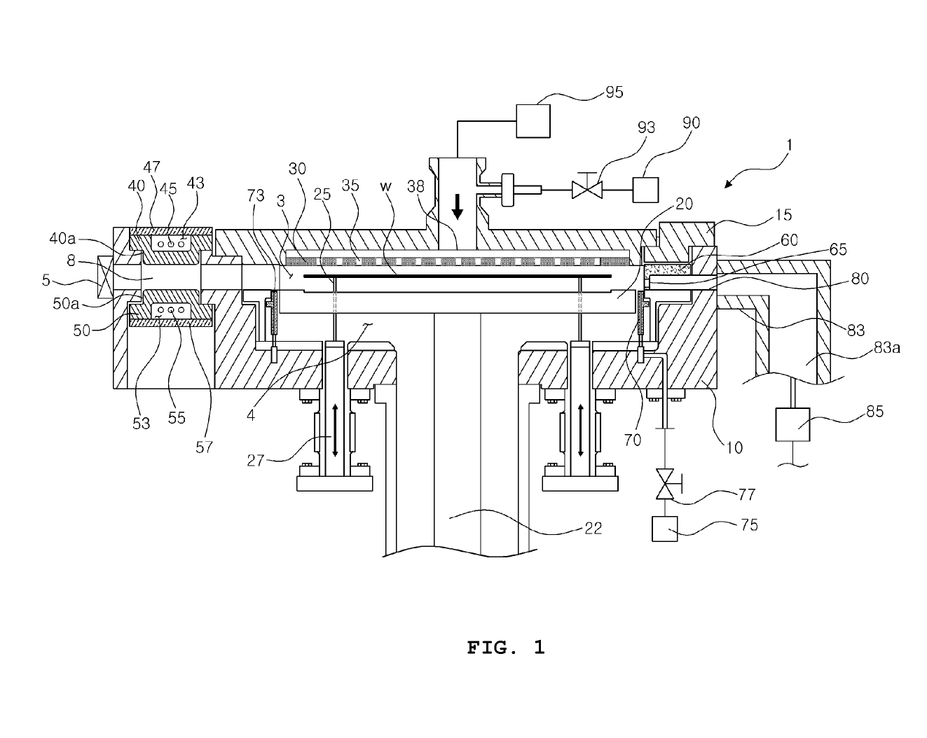

Hereinafter, exemplary embodiments of the present invention will be described in detail with reference to FIGS. 1 to 3. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the shapes of components are exaggerated for clarity of illustration. Also, although a substrate is described as an example, the present invention is applicable to various objects to be processed.

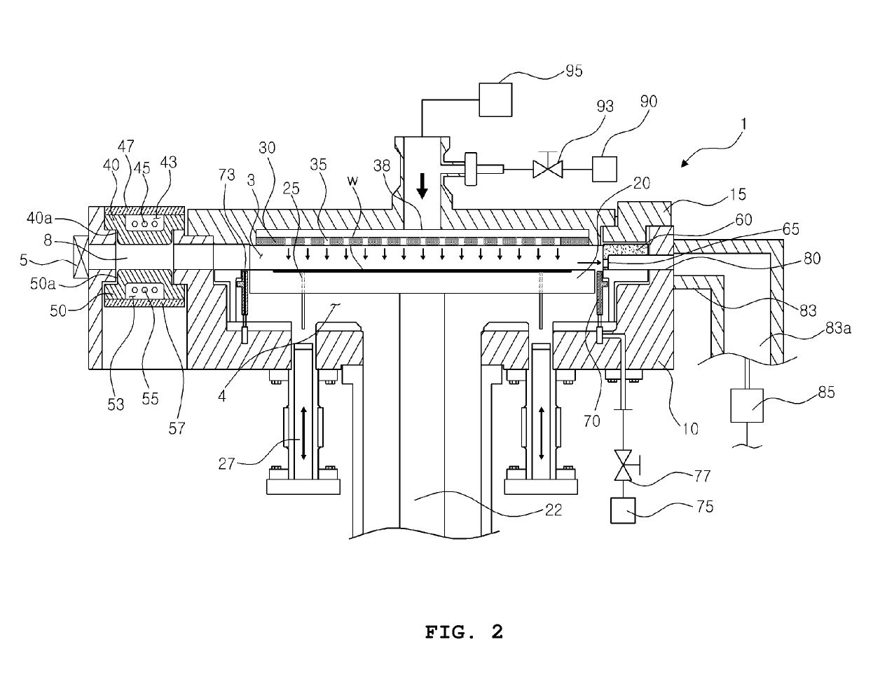

FIG. 1 is a schematic view of a substrate processing apparatus according to an embodiment of the present invention, and FIG. 2 is a schematic view illustrating a process progression state of the substrate processing apparatus of FIG. 1. Referring to FIG. 1, a substrate processing apparatus 1 includes a main chamber 10 and a chamber cover 15. The main chamber 10 has an opened upper side. Also, a passage 8 through which a substrate W is accessible is defined in a side of the main chamber 10. The substrate W is loaded into or unloaded from the main chamber 10 through the passage 8 defined in the side of the main chamber 10. A gate valve 5 is disposed outside the passage 8. The passage 8 may be opened or closed by the gate valve 5.

The chamber cover 15 covers the opened upper side of the main chamber 10 to block access from the outside. A gas supply hole 38 passes through a ceiling wall of the chamber cover 15. Thus, a process gas is supplied into the main chamber 10 through the gas supply hole 38. The process gas is connected to a process gas storage tank 90. Also, a process gas inflow rate may be adjusted by opening or closing a valve 93. The process gas may be supplied through the gas supply hole 38 to perform a deposition process. As necessary, a cleaning gas in which NF₃ and Ar are mixed may be supplied into the main chamber 10 through a remote plasma system (RPS) 95 connected to the gas supply hole 38 to perform a cleaning process within the main chamber 10.

A showerhead 30 having a plurality of diffusion holes 35 is installed on a lower surface of the chamber cover 15. The showerhead 30 diffuses the process gas supplied through the gas supply hole 38 onto the substrate W. A susceptor 20 is installed within the main chamber 10. Also, the susceptor 20 is disposed under the substrate W to heat the substrate W. The susceptor 20 may have an area greater than that of the substrate W to uniformly heat the substrate W. Also, the susceptor 20 may have a circular disk shape corresponding to that of the substrate W. A heater (not shown) is installed within the susceptor 20. Also, the susceptor 20 may be rotatable.

A lift pin 25 may pass through a side portion of the susceptor 20. The substrate W transferred through the passage 8 is loaded on an upper portion of the lift pin 25. A lift pin elevation unit 27 is disposed under the lift pin 25 to elevate the lift pin 25. As shown in FIG. 2, when the substrate W is loaded, the lift pin 25 may descend to seat the substrate W on a top surface of the susceptor 20, thereby performing the deposition process.

A process space 3 is defined between the susceptor 20 and the showerhead 30. Processes with respect to the substrate W are performed in a state where the substrate W is loaded into the process space 3. The main chamber 10 is recessed from the bottom surface thereof to define an auxiliary space 4 in which the susceptor 20 is disposed. A nozzle ring 70 is disposed along a circumference of the susceptor 20 in the auxiliary space 4 to prevent the process gas from being introduced through the susceptor 20 and a gap between the bottom surface of the main chamber 10 and the susceptor 20. The nozzle ring 70 has a plurality of spray holes 73 to receive an inert gas from an inert gas storage tank 75, thereby spraying the inert gas into the process space 3.

As shown in FIG. 1, the passage 8 has an opening 40a, 50a in each of upper and lower portions thereof and the opening 40a, 50a communicate with the passage 8. Upper and lower heating blocks 40 and 50 close the upper and lower openings have upper and lower installation spaces 43 and 53. Upper and lower heaters 45 and 55 are disposed in the upper and lower installation spaces 43 and 53, respectively. The upper and lower heating blocks 40 and 50 may previously heat the substrate entering through the passage 8. The upper and lower heating blocks 40 and 50 may be vertically disposed symmetrical to each other with respect to a position of the passage 8 into which the substrate w enters to preliminarily heat top and bottom surfaces of the substrate W at the same temperature.

The lower heating block 50 has an opened lower side. A lower cover 57 covers the opened lower side of the lower heating block 50 to isolate the inside of the lower heating block 50 from the outside. Thus, the lower installation space 53 defined inside the lower heating block 50 is separated from the process space 3 as well as is blocked from the outside. Similarly, the upper heating block 40 has an opened upper side. An upper cover 47 covers the opened upper side of the upper heating block 40 to isolate the inside of the upper heating block 70 from the outside. Thus, the upper installation space 43 defined inside the upper heating block 40 is separated from the process space 3 as well as is blocked from the outside.

The upper and lower heaters 45 and 55 are disposed in the upper and lower installation spaces 43 and 53, respectively. A kanthal heater may be used as each of the upper and lower heaters 45 and 55. Kanthal may be a Fe—Cr—Al alloy, wherein iron is used as a main material. Thus, kanthal may have high heat-resistance and electric-resistance.

The upper heater 45 and the lower heater 55 are arranged in a direction parallel to the substrate W. The upper heater 45 heats the upper heating block 40. That is, the upper heater 45 indirectly heats the moving substrate W through the upper heating block 70 by radiation. Similarly, the lower heater 55 heats the lower heating block 50. That is, the lower heater 55 indirectly heats the substrate W through the lower heating block 50. Thus, a heat deviation on the substrate W according to positions of the upper or lower heaters 45 or 55 may be minimized. A temperature deviation due to the positions of the upper and lower heaters 45 and 55 may be mitigated through the upper and lower heating blocks 40 and 50 to minimize the heat deviation on the substrate W. The heat deviation on the substrate W may cause process non-uniformity. As a result, a thickness deviation of a deposited thin film may occur.

Thus, according to the present invention, the substrate W may be previously heated on the passage 8. That is, the substrate W may be preliminarily heated before the substrate W is loaded so as to prevent the warpage of the substrate W as well as reduce a time required for heating the substrate W seated on the susceptor 20 at a deposition process temperature. Since the substrate W has a circular disk shape, the upper and lower heating blocks 40 and 50 for preliminarily heating the substrate W may be connected to a control unit (not shown) that controls the upper and lower heating blocks 40 and 50 so that the upper and lower heating blocks 40 and 50 are operated for different times and at different temperatures for zones of the central and edge portions of the substrate W, thereby performing the preliminary heating.

As shown in FIG. 2, the upper and lower heaters 45 and 55 are respectively installed in the upper and lower installation spaces 43 and 53 to preliminarily heat the substrate W through the upper and lower heating blocks 40 and 50. The substrate W may pass through the upper and lower heating blocks 40 and 50 at a preset speed and time by the control unit and thus be preliminarily heated. Also, each of the upper and lower heating blocks 40 and 50 may be formed of a material such as high purity quartz. Quartz may have relatively high structural strength and be chemically inactivated against deposition process environments. Thus, a plurality of liners disposed to protect an inner wall of the chamber may also be formed of a quartz material.

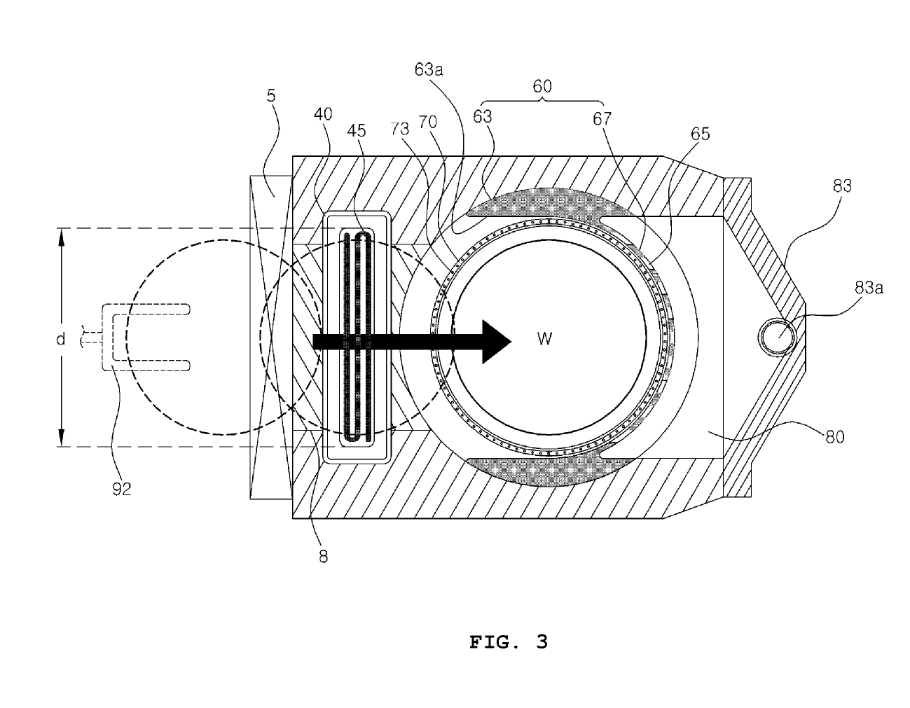

The process gas supplied into the process space 3 through the gas supply hole 38 is diffused through the showerhead 30 and then deposited on the substrate W. After the deposition process, reaction byproducts or reaction gases may be pumped through an exhaust passage 80 defined in a side opposite to the passage 8. An exhaust pump 85 may be connected to the exhaust passage 80 through an exhaust port 83 to pump the process gas introduced into the process space 3, thereby discharging the pumped process gas to the outside. The susceptor 20 may be rotatable to uniformly deposit the diffused process gas on the substrate W. A flow guide 60 may be disposed outside the susceptor 20 to guide a flow of the process gas so that the process gas flows toward the exhaust passage 80. A moving path of the substrate W and a structure of the flow guide 60 will be described with reference to FIG. 3.

FIG. 3 is a cross-sectional view illustrating a process space of the substrate processing apparatus of FIG. 1. Referring to FIG. 3, the substrate W in state of being disposed on an end effector 92 enters into the passage 8 through the gate valve 5. The entering substrate W may be preliminarily heated while passing through the upper and lower heating blocks 40 and 50. Each of the upper and lower heating blocks 40 and 50 may have a width d substantially equal to or greater than a diameter of the substrate W. As described above, the intensity of each of the upper and lower heaters 45 and 55 installed in the upper and lower installation spaces 43 and 53 may be controlled according to the zones of the substrate W by the control unit. In addition, the control unit may control a moving speed of the substrate W.

The preliminarily heated substrate W is seated on the susceptor 20 to perform the deposition process with respect to the substrate W.

The process gases may be diffused onto the substrate through the showerhead 30. The susceptor 20 on which the substrate W is seated may be rotated so that the process gases are uniformly deposited on the substrate W. The flow guide 60 may be provided to uniformly deposit the process gases on the substrate W and minimize the process space 3 in which the substrate W does not react with the process gas. The flow guide 60 includes a linear guide part 63 disposed in the main chamber 10 to minimize a space in which the substrate W does not react with the process gas outside the susceptor 20 and a circular guide part 67 guide a uniform flow of the process gases toward the exhaust passage 80. The linear guide part 63 has a guide surface 63a that is substantially parallel to a moving direction of the substrate W (or a longitudinal direction of the passage 8). Since the circular guide part 67 has a plurality of guide holes, the process gases pumped through the exhaust passage 80 and discharged to the outside may be uniformly dispersed.

Thus, the substrate W may be preliminarily heated by using the upper and lower heating blocks 40 and 50 disposed on the upper and lower portions of the passage 8 to prevent the warpage of the substrate due to non-uniform thermal gradient of the substrate W. Especially, since the substrate W is heated by the upper and lower heating blocks 40 and 50 in the type of scanning while the substrate W is moving, the heats of the upper and lower heating blocks 40 and 50 are not concentrated on the substrate W locally and the substrate W can be preliminarily heated to high temperature rapidly.

Also, since the substrate W is preliminarily heated at a preset temperature to load the preliminarily heated substrate W on the lift pin 25, a time required for heating the substrate W up to the deposition temperature that is required for the deposition process may be reduced to improve productivity. Preliminary heating is performed during the loading process of the substrate W, a time for preliminary heating is not required. If the substrate W is heated to the deposition temperature only by the susceptor 20, a heating time is increased by the low speed of heating for preventing the warpage of the substrate W, the warpage of the substrate W is occurred by the high speed of heating for minimizing the heating time.

In addition, the flow guide 60 may be installed to minimize the process space. Also, the nozzle ring 70 may be installed to previously block the process gases introduced into an empty space between the susceptor 20 and the main chamber 10, thereby maximizing the reactivity between the substrate W and the process gases.

Although the present invention is described in detail with reference to the exemplary embodiments, the invention may be embodied in many different forms. Thus, technical idea and scope of claims set forth below are not limited to the preferred embodiments.

What is claimed is:

1. A substrate processing apparatus comprising:
a chamber body having an opened upper side, the chamber body comprising a passage defined in a side thereof so that a substrate is loaded or unloaded through the passage;
a chamber cover disposed on the opened upper side of the chamber body to cover the opened upper side of the chamber body, the chamber cover providing a process space in which the process with respect to the substrate is performed;
a susceptor disposed within the process space to heat the substrate disposed on a upper surface of the susceptor;
a heating block disposed on an upper or lower portion of the passage to preliminarily heat the substrate loaded through the passage; and
an end effector moving with the substrate through the passage and loading the substrate on the upper surface of the susceptor.

2. The substrate processing apparatus of claim 1, wherein the chamber body has upper and lower openings that are respectively defined in the upper and lower portions of the passage, and
the substrate processing apparatus comprises:
an upper heating block fixed to the upper opening, the upper heating block having an upper installation space separated from the process space; and
a lower heating block fixed to the lower opening, the lower heating block having a lower installation space separated from the process space.

3. The substrate processing apparatus of claim 2, wherein an upper side of the upper heating block and a lower side of the lower heating block are opened, and
the substrate process apparatus comprises:
an upper cover covering the opened upper side of the upper heating block to isolate the upper installation space from the outside; and
a lower cover covering the opened lower side of the lower heating block to isolate the lower installation space from the outside.

4. The substrate processing apparatus of claim 1, further comprising a nozzle ring disposed outside the susceptor to surround the susceptor, the nozzle ring spraying an inert gas upward.

5. The substrate processing apparatus of claim 1, wherein the chamber body has an exhaust passage defined in a side opposite to the passage, and
the substrate process apparatus further comprises a flow guide disposed outside the susceptor to guide the process gas toward the exhaust passage,
wherein the flow guide comprises:
a circular guide part having an arc shape that is concentric with the susceptor, the circular guide having a plurality of guide holes; and
linear guide parts connected to both sides of the circular guide part and disposed on both sides of the susceptor, respectively, each of the linear guide parts having a guide surface that is substantially parallel to a loading direction of the substrate.
